(19) United States
(12) Patent Application Publication
(10) Pub. No.: US 2026/0154484 A1
(43) Pub. Date: Jun. 4, 2026

(54) REGISTER TRANSFER LEVEL (RTL) CODE BLOCK STORAGE AND ANALYSIS

(71) Applicant: Singularity Dynamics Private Limited, Bangalore (IN)

(72) Inventor: Harish Kumar, Bangalore (IN)

(21) Appl. No.: 19/404,029

(22) Filed: Dec. 1, 2025

Related U.S. Application Data
(60) Provisional application No. 63/726,342, filed on Nov. 29, 2024.

(51) Int. Cl. G06F 30/33; G06F 11/362; G06F 30/327

(52) U.S. Cl. CPC G06F 30/33; G06F 11/3624; G06F 30/327

(57) ABSTRACT

Disclosed subject matter relates to verification and debugging tool and method for providing Register Transfer Level (RTL) code block storage and analysis. Verification and debugging tool includes input interface configured to receive RTL code in Hardware Description Language (HDL). Further, verification and debugging tool includes RTL parser configured to parse RTL code, and generate abstract syntax tree representing syntactic structure of RTL code. Thereafter, verification and debugging tool includes graph converter adapted to convert abstract syntax tree into RTL directed graph. Furthermore, verification and debugging tool includes memory configured to store node block structures. Each node block structure includes at least one of pointers to fan-in nodes, fanout nodes and one or more custom fields indicating behavior description of node. Finally, verification and debugging tool includes visual display configured to display RTL directed graph. Directional links indicate signal flow both upstream and downstream, enabling simultaneous visualization.

### CROSS-REFERENCE TO RELATED APPLICATIONS

The present application claims the benefit of priority to U.S. Provisional Application No. 63/726,342, filed on Nov. 29, 2024; the contents of which are hereby incorporated by reference herein in their entirety.

### TECHNICAL FIELD

The present disclosure relates to electronic design. Particularly, the present disclosure relates to a technique of providing Register Transfer Level (RTL) code block storage and analysis.

### BACKGROUND

Modern electronic design is typically performed with Computer-Aided Design (CAD) tools or Electronic Design Automation (EDA) systems. To design an Integrated Circuit (IC) device, a designer first creates high-level behavior descriptions of the IC device using a hardware description language (HDL) such as Verilog and VHDL. As the complexity of the IC devices is growing exponentially due to changes such as shrinking in size of the IC chips and integration of more functionality onto a single IC chip, the behavioral descriptions of the devices are also becoming complex due to a large number of code blocks written in HDL for the IC chips.

A verification engineer usually identifies and resolves the errors or bugs present in the written code blocks using verification and debugging tools. With the existing verification and debugging tools, the verification engineer needs to perform multiple iterations in the process of identifying and resolving errors in a functional block of the RTL code written in text format. This makes the process of debugging very complex and time-consuming for the verification engineer. Additionally, the verification step, namely the process of ensuring the behavior of the chip is according to the specification under any and every use case, consisting of the process of finding root causing and fixing bugs is a laborious iterative process and is recognized in the industry as a long pole and the deciding factor for Tape out and productization schedule.

Therefore, there is a need for a verification and debugging tool which enables significantly higher efficiency of the verification step and thereby reducing the time duration of the verification step.

The information disclosed in this background of the disclosure section is only for enhancement of understanding of the general background of the invention and should not be taken as an acknowledgement or any form of suggestion that this information forms the prior art already known to a person skilled in the art.

### SUMMARY

Disclosed herein is a verification and debugging tool for Register Transfer Level (RTL) code. The verification and debugging tool comprises an input interface configured to receive RTL code in a Hardware Description Language (HDL). Further, the verification and debugging tool comprises an RTL parser configured to parse the RTL code, and generate an abstract syntax tree representing the syntactic structure of the RTL code. Thereafter, the verification and debugging tool comprises a graph converter adapted to convert the abstract syntax tree into an RTL directed graph. The RTL directed graph comprises plurality of code blocks. Each of the plurality of code blocks is represented as a node. Each node represents a functional block of the RTL code and each node comprise a node identifier, a fan-in parameter defining one or more input nodes, and a fanout parameter defining one or more output nodes. Furthermore, the verification and debugging tool comprises a memory configured to store node block structures. Each node block structure comprises at least one of pointers to fan-in nodes, fanout nodes and one or more custom fields indicating behavior description of the node. Finally, the verification and debugging tool comprises a visual display configured to display the RTL directed graph, wherein directional links indicate signal flow both upstream and downstream, enabling simultaneous visualization of multiple code blocks and corresponding interconnections.

Further, disclosed herein is a method of providing Register Transfer Level (RTL) code block storage and analysis. The method includes receiving RTL code in a Hardware Description Language (HDL). Further, the method includes parsing the RTL code, and generating an abstract syntax tree representing the syntactic structure of the RTL code. Thereafter, the method includes converting the abstract syntax tree into an RTL directed graph. The RTL directed graph comprises plurality of code blocks. Each of the plurality of code blocks is represented as a node. Each node represents a functional block of the RTL code and each node comprise a node identifier, a fan-in parameter defining one or more input nodes, and a fanout parameter defining one or more output nodes. Furthermore, the method includes storing node block structures. Each node block structure comprises at least one of pointers to fan-in nodes, fanout nodes and one or more custom fields indicating behavior description of the node. Finally, the method includes displaying the RTL directed graph. Directional links indicate signal flow both upstream and downstream, enabling simultaneous visualization of multiple code blocks and corresponding interconnections.

Furthermore, the present disclosure relates to a non-transitory computer readable medium including instructions stored thereon that when processed by at least one processor, cause a verification and debugging tool to perform operations comprising receiving RTL code in a Hardware Description Language (HDL). Further, the instructions cause the processor to parse the RTL code, and generate an abstract syntax tree representing the syntactic structure of the RTL code. Thereafter, the instructions cause the processor to convert the abstract syntax tree into an RTL directed graph. The RTL directed graph comprises plurality of code blocks. Each of the plurality of code blocks is represented as a node. Each node represents a functional block of the RTL code and each node comprise a node identifier, a fan-in parameter defining one or more input nodes, and a fanout parameter defining one or more output nodes. Furthermore, the instructions cause the processor to store node block structures. Each node block structure comprises at least one of pointers to fan-in nodes, fanout nodes and one or more custom fields indicating behavior description of the node. Finally, the instructions cause the processor to display the RTL directed graph. Directional links indicate signal flow both upstream and downstream, enabling simultaneous visualization of multiple code blocks and corresponding interconnections.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE ACCOMPANYING DRAWINGS

The accompanying drawings, which are incorporated in and constitute a part of this disclosure, illustrate exemplary embodiments and, together with the description, explain the disclosed principles. In the figures, the left-most digit(s) of a reference number identifies the figure in which the reference number first appears. The same numbers are used throughout the figures to reference like features and components. Some embodiments of system and/or methods in accordance with embodiments of the present subject matter are now described, by way of example only, and regarding the accompanying figures, in which:

FIG. 1 shows an exemplary environment of providing Register Transfer Level (RTL) code block storage and analysis, in accordance with some embodiments of the present disclosure;

FIG. 2A illustrates a node block structure, in accordance with an embodiment of the present disclosure;

FIG. 2B illustrates an exemplary code block structure, in accordance with an embodiment of the present disclosure;

FIG. 3 shows a flowchart illustrating method of providing Register Transfer Level (RTL) code block storage and analysis, in accordance with some embodiments of the present disclosure;

FIG. 4 illustrates a block diagram of an exemplary computer system for implementing embodiments consistent with the present disclosure.

It should be appreciated by those skilled in the art that any block diagrams herein represent conceptual views of illustrative systems embodying the principles of the present subject matter. Similarly, it will be appreciated that any flow charts, flow diagrams, state transition diagrams, pseudo code, and the like represent various processes which may be substantially represented in computer readable medium and executed by a computer or processor, whether such computer or processor is explicitly shown.

### DETAILED DESCRIPTION

In the present document, the word “exemplary” is used herein to mean “serving as an example, instance, or illustration.” Any embodiment or implementation of the present subject matter described herein as “exemplary” is not necessarily to be construed as preferred or advantageous over other embodiments.

While the disclosure is susceptible to various modifications and alternative forms, specific embodiment thereof has been shown by way of example in the drawings and will be described in detail below. It should be understood that it is not intended to limit the disclosure to the specific forms disclosed, but on the contrary, the disclosure is to cover all modifications, equivalents, and alternative falling within the scope of the disclosure.

The terms “comprises”, “comprising”, “includes”, or any other variations thereof, are intended to cover a non-exclusive inclusion, such that a setup, device, or method that comprises a list of components or steps does not include only those components or steps but may include other components or steps not expressly listed or inherent to such setup or device or method. In other words, one or more elements in a system or identity server proceeded by “comprises . . . a” does not, without more constraints, preclude the existence of other elements or additional elements in the system or method.

The terms like “at least one” and “one or more” may be used interchangeably throughout the description.

The terms like “verification and debugging tool”, “verification tool”, “debugging tool” and “tool” may be used interchangeably throughout the description.

The terms like “RTL code” and “code” may be used interchangeably throughout the description.

The terms like “circuit designer” and “designer” may be used interchangeably throughout the description.

The present disclosure relates to a verification and debugging tool that represents the RTL code and their interconnections in the form of nodes. The RTL code is a coding style used in digital system design and computer engineering, that is written using Hardware Description Language (HDL) like Verilog or VHDL. The RTL code defines the functioning of a digital circuit that may include one or more code blocks. A code block is an independent piece of the RTL code started and terminated by delimiters such as BEGIN and END, or semicolon in case of an assign statement, etc. In particular, RTL describes how the data transforms and flows from one register to another. The transformation of data is performed by combinational logic that exists between the registers. The operation of the RTL code is verified by using the verification tool and if any errors or problems arise in the code during its operation, the problems are solved or debugged by the debugging tool. The tool provides a provision to store the various RTL codes in the form of nodes. In an exemplary embodiment, the tool may convert the RTL code into an abstract syntax tree and then convert the abstract syntax tree into an inter-connected form of the functional blocks. In an exemplary embodiment, the inter-connected form of the functional blocks is a directed graph and is stored in the form of a node. The tool also provides interconnections from one functional block to other functional blocks.

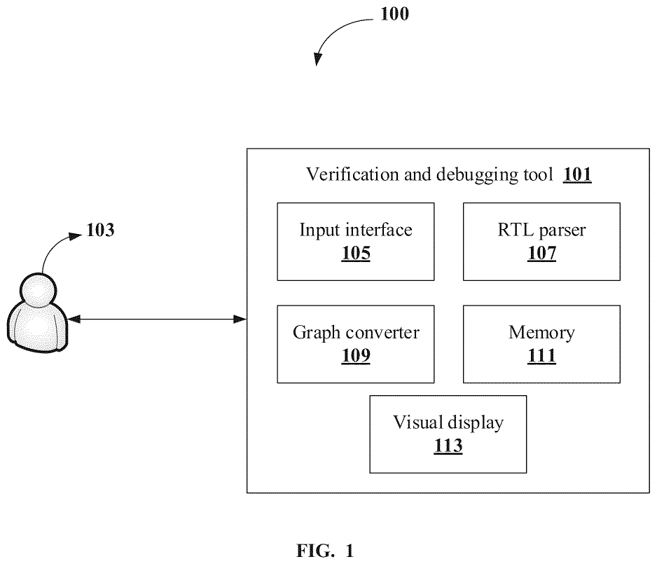

FIG. 1 shows an exemplary environment of providing Register Transfer Level (RTL) code block storage and analysis, in accordance with some embodiments of the present disclosure.

Exemplary environment 100 includes a verification and debugging tool 101 and a user 103. The verification and debugging tool 101 may include an input interface 105, an RTL parser 107, a graph converter 109, a memory 111 and a visual display 113. The user 103 may interact with the verification and debugging tool 101 using the input interface 105 and the visual display 113. The input interface 105 may include, without limitation, keyboards, mouse, touchscreens, and the like, which allow direct user interaction. The input interface 105 may also receive input from any sources provided by the user 103. As an example, the input interface 105 may receive input from Uniform Resource Locator (URL). The output may be displayed on the visual display 113. As an example, the visual display 113 may include, without limitation, an electronic screen, a touchscreen and the like, which allows display of the output. In an embodiment, the verification and debugging tool 101 may be a computing device. As an example, the computing device may be any device used by the user 103 such as, but not limited to, mobile phones, smartphones, laptops, and Personal Computers (PCs). In some embodiments, the verification and debugging tool 101 may be configured within the computing device (not shown in figure).

In an embodiment, the input interface 105 may be configured to receive RTL code in a Hardware Description Language (HDL) from the user 103. The HDLs may include, without limitation, at least one of Verilog and VHSIC Hardware Description Language (VHDL). As an example, the user 103 may be a circuit designer. The RTL code may describe behavior and component connections of a circuit such as an Integrated Circuit (IC). The RTL code may include one or more code blocks describing the operations of one or more entities/components of the circuit. In an embodiment, the input interface 105 may be further configured to validate syntax of the RTL code. If syntax error is detected, the syntax error may be displayed on the visual display 113 allowing the user 103 to edit the RTL code to rectify the syntax error. The input interface 105 may also detect any error which may affect execution of the RTL code.

In an embodiment, upon receiving the RTL code, the RTL parser 107 may be configured to parse the RTL code. In an embodiment, the RTL parser 107 may parse the RTL code by performing lexical and syntactic analysis to identify structural elements such as modules, signals, assignments, and control statements. Based on this analysis, the RTL parser 107 may generate an Abstract Syntax Tree (AST) that represents the hierarchical syntactic structure of the RTL code. The AST may include nodes corresponding to language constructs and captures parent-child relationships between statements, thereby providing a structured and unambiguous representation of the RTL code for subsequent transformation into an RTL directed graph.

In an embodiment, upon generating the AST, the graph converter 109 may be configured to convert the AST into the RTL directed graph. In an embodiment, each node of the RTL directed graph may include, without limitation, at least one of a forward pointer to nodes for which the current node forms an input, and a backward pointer to nodes from which the current node receives an input. The graph converter 109 may be further configured to represent signals of the RTL code as vertices of the RTL directed graph. The graph converter 109 may also provide one or more customizable display options for the RTL directed graph. The customizable options may enable the user 103 to modify the visual representation of the RTL directed graph to suit specific debugging or analysis requirements. The one or more customizable display options may include, without limitation, color coding for different signal types or logic states, adjustable node sizes to emphasize critical modules, selectable layers for viewing control flow or data flow independently, and variable line thickness or styles to indicate signal width or type. Additional customization may include zoom functionality for detailed inspection of individual nodes, dynamic visual effects to represent changes in signal values over time, and grouping of related nodes into functional sections. These customizable display options enhance clarity, improve navigation within complex RTL designs, and facilitate efficient identification of design issues during verification and debugging. In some embodiments, the RTL directed graph may be configured to display at least one of control flow and data flow. At least one of the control flow and the data flow may be displayed in a visually distinguishable manner. The visual distinction between the control flow and the data flow may be obtained using one of different arrow styles or different colors. In other words, the visual distinction between control flow and data flow within the RTL directed graph is achieved through the use of differentiated graphical indicators. In one embodiment, the distinction is provided by employing different arrow styles, such as solid arrows for data flow and dashed arrows for control flow, or by varying arrowhead shapes to represent signal types. Alternatively, the distinction may be implemented using different colors for the respective flows, enabling clear and intuitive identification of control signals versus data paths. These visual differentiation techniques enhance the readability of complex RTL designs and facilitate efficient debugging and verification by allowing users to quickly interpret the nature of each connection within the graph.

In an embodiment, upon converting the AST into the RTL directed graph, the memory 111 may be configured to store node block structures. Each node block structure may include, without limitation, at least one of pointers to fan-in nodes, fanout nodes and one or more custom fields indicating behavioral description of the node. The nodes in the RTL directed graph may be linked to each other through pointers. The link between the one or more nodes may represent a link between one or more code blocks. The links between the one or more code blocks may have arrows to describe the direction of the data flow and the control/signal flow. Each code block of the one or more code blocks of the RTL directed graph may have a structure known as code block structure of the RTL. Accordingly, the directed graph generated from the graph converter 109 may be used for further optimization and synthesis.

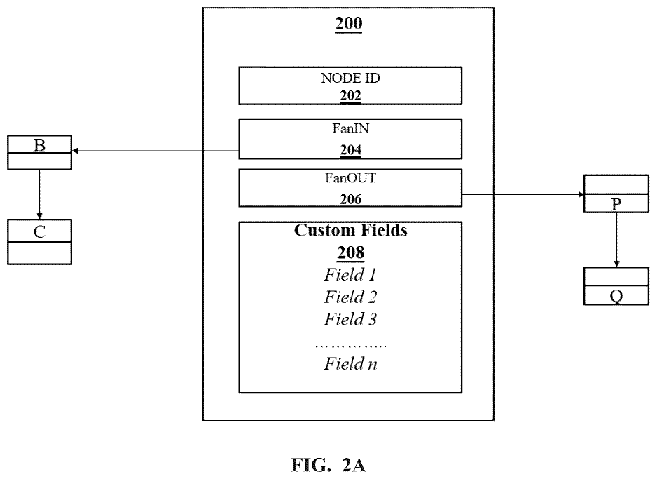

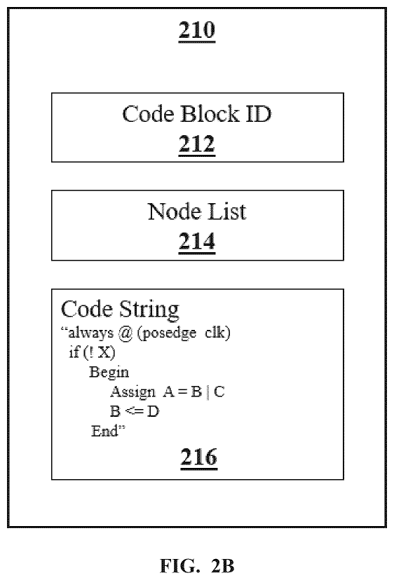

In an exemplary embodiment, node defines functional element e.g., a logic or any other component in a circuit. The graphical representation depicts relationship and interaction between different nodes where nodes are represented as vertices, and the connections between different nodes are represented as edges. This visual format helps designers understand the flow of data and control signals within the circuit, making it easier to analyze and optimize the design. Further, this abstraction helps in visualizing the overall architecture and RTL, and enables multiple tasks including verification, debug, identifying critical paths or bottlenecks among others. Details on the node block structure are presented in FIGS. 2A and 2B.

In an embodiment, upon storing the node block structures, the visual display 113 may be configured to display the RTL directed graph. Directional links in the directed graph may indicate signal flow both upstream and downstream, enabling simultaneous visualization of multiple code blocks and corresponding interconnections. The visual display 113 may also include an output interface configured to display debug information related to RTL code analysis and results (not shown in figure). In some embodiments, the visual display 113 and the output interface may be same. The visual display 113 and the output interface may also display results in a graphical format. In an embodiment, the visual display 113 may be configured to support zoom functionality for viewing details of individual code blocks or nodes. The zoom functionality may allow the user 103 to focus on specific areas of the RTL directed graph while preserving the ability to return to an overall view. The visual display 113 may also include user interface which may allow the user interactions within the visual display 113. The user interface may allow the user 103 to group multiple code blocks into functional sections. The visual display 113 provides an integrated environment for real-time analysis and debugging of RTL designs. By enabling simultaneous visualization of structural elements, signal states, and dynamic behavior, the system improves design comprehension and accelerates error detection. These features collectively enhance the efficiency of verification workflows and reduce the time required for identifying and resolving design issues.

FIG. 2A illustrates a node block structure 200 of a node in accordance with an embodiment of the present disclosure. A node block is a data structure which is unique per Node and contains information relating to pointer to the generating Code Block (specific RTL code that represents the logic for computing the value of that Node), a list of fan-in and Fanout nodes and additional information related to node. In an embodiment, node block structure 200 may include a node identifier (ID) 202. The node ID 202 may be a unique ID for each node among one or more nodes in a code block. In an embodiment, one or more code blocks may include node A.

The node block structure 200 may include a fan-in parameter 204. The node A may be a logic function of one or more nodes. The fan-in 204 may define the number of nodes that are input to the node A. In an embodiment, the node A in a code block may be the logic function of node B and node C. In an embodiment, the nodes B and C may be stored as a linked list, but is not limited to. Further, the node B may be function of node D. Thus, fan-in for node B may be 1 i.e. node D. However, the Fan-in for node A is considered as 2 only i.e. node B and node C. In an exemplary embodiment, the node B and C are stored in the linked list format in the node structure thus, the Node A may be connected to the node B and the node C through backward pointers.

The node block structure 200 may include a fanout parameter 206. The node A may be an input to one or more nodes. The Fanout 206 may define the number of nodes that are logic functions of the node A. In an embodiment, the node A in a code block may be the input to node P and node Q. In other words, the node P and the node Q may be logic functions of the node A. Further, the node Q may be input to a node U. Thus, Fanout for the node Q may be 1 i.e. the node U. The Fanout for the node A may be 2 only i.e. the node P and the node Q. Similar to fan-in, the Fanout value for the node A is stored in the linked list format. Thus, the node A may be connected to the node P and the node Q through forward pointers.

The node block structure 200 may include custom fields 208. The custom fields 208 may define the behavior description of the node A. The custom fields 208 may be one or more lines of the RTL code. A skilled person may appreciate that the custom field present in the node block structure may be customized/specified by the designer based on the code block requirement.

FIG. 2B illustrates a code block structure 210 in accordance with an embodiment of the present disclosure. In an embodiment, a code block for a node A may be defined as a code block in which the node A is assigned. In an embodiment, one or more code blocks may be defined for the node A.

The code block structure 210 may include a code block identifier ID 212. The code block ID 212 may be a unique identifier for each code block among the one or more code blocks of the RTL code.

The code block structure 210 may include a node list 214. The node list 214 may include information of one or more nodes referenced in the current code block. In an embodiment, the node list 214 may be a hash of names of the one or more nodes referenced in the current code block, but not limited thereto. One or more nodes in a code block may be connected to one or more nodes in another code block through the pointers.

The code block structure 210 may include a code string 216. The code string 216 may define behaviour description of the current code block. The code string 216 may be one or more lines of the RTL code.

As stated in the exemplary scenario, once the RTL code has been converted into the directed graph, the verification and debugging tool 101 with a graphical visualizer may display the one or more code blocks into the graphical format. Graphical representation offers a powerful means to visualize and optimize the node block structures that may enhance the design process, making it more efficient and manageable as well. The exemplary scenario may be presented to make the reader understand the subject matter, however, there may be various other aspects and embodiments of the present disclosure as well, other aspects and embodiments will be apparent to those skilled in the art. The various aspects and embodiments disclosed herein are for purposes of illustration and are not intended to be limiting, with the true scope and spirit being indicated by the detailed description.

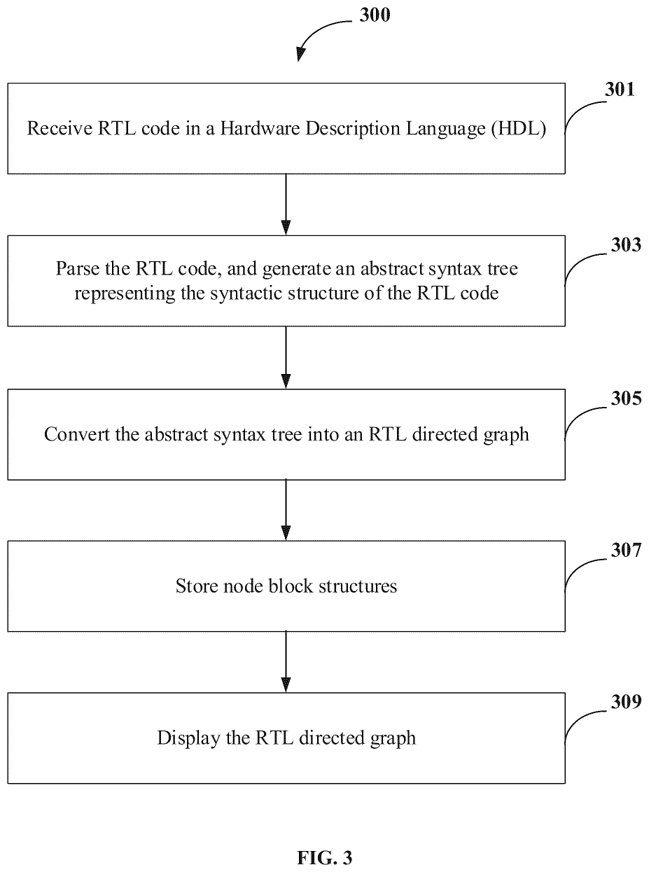

FIG. 3 is a flowchart illustrating a method of providing Register Transfer Level (RTL) code block storage and analysis, in accordance with some embodiments of the present disclosure.

As illustrated in FIG. 3, the method 300 may include one or more blocks illustrating a method of providing Register Transfer Level (RTL) code block storage and analysis, using the verification and debugging tool 101 illustrated in FIG. 1. The method 300 may be described in the general context of computer executable instructions. Generally, computer executable instructions can include routines, programs, objects, components, data structures, procedures, modules, and functions, which perform specific functions or implement specific abstract data types.

The order in which the method 300 is described is not intended to be construed as a limitation, and any number of the described method blocks can be combined in any order to implement the method. Additionally, individual blocks may be deleted from the methods without departing from the scope of the subject matter described herein. Furthermore, the method can be implemented in any suitable hardware, software, firmware, or combination thereof.

At block 301, the method 300 includes receiving, by a processor of the verification and debugging tool 101, RTL code in a Hardware Description Language (HDL). The HDLs may include at least one of Verilog and VHSIC Hardware Description Language (VHDL). Further, the processor may validate syntax of the RTL code.

At block 303, the method 300 includes parsing, by the processor, the RTL code, and generating an abstract syntax tree representing the syntactic structure of the RTL code.

At block 305, the method 300 includes converting, by the processor, the abstract syntax tree into an RTL directed graph. The RTL directed graph comprises plurality of code blocks. Each node of the RTL directed graph may include at least one of a forward pointer to nodes for which the current node forms an input, and a backward pointer to nodes from which the current node receives an input. The processor may represent signals of the RTL code as vertices of the RTL directed graph. Further, the processor may provide one or more customizable display options for the RTL directed graph. The processor may also provide one or more customizable display options for the RTL directed graph. The one or more customizable display options may include, without limitation, at least one of color coding for different types of signals, adjustable node sizes, and selectable layers of data flow representation. Further, zoom functionality may be supported for viewing details of individual code blocks or nodes. The zoom functionality allows a user 103 to focus on specific areas of the RTL directed graph while preserving the ability to return to an overall view. The RTL directed graph may be configured to display at least one of control flow and data flow. At least one of the control flow and the data flow is displayed in a visually distinguishable manner. The visual distinction between the control flow and the data flow may be obtained using one of different arrow styles or different colors.

At block 307, the method 300 includes storing, by the processor, node block structures. Each node block structure comprises at least one of pointers to fan-in nodes, fanout nodes and one or more custom fields indicating behavior description of the node.

At block 309, the method 300 includes displaying, by the processor, the RTL directed graph. Directional links indicate signal flow both upstream and downstream, enabling simultaneous visualization of multiple code blocks and corresponding interconnections.

### Computer System

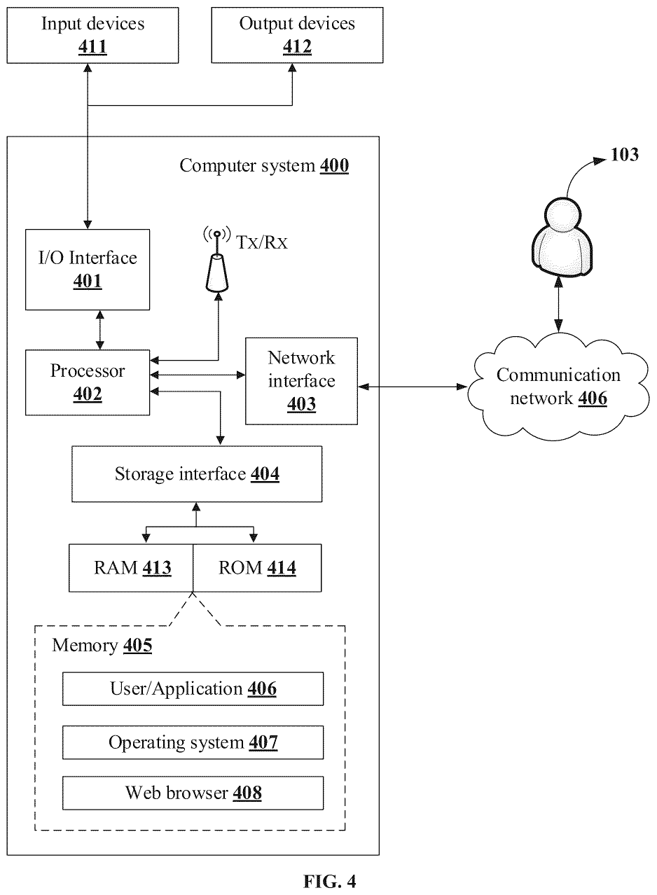

FIG. 4 illustrates a block diagram of an exemplary computer system 400 for implementing embodiments consistent with the present disclosure. In an embodiment, the computer system 400 may be a verification and debugging tool 101 illustrated in FIG. 1. The computer system 400 may include a central processing unit (“CPU” or “processor” or “memory controller”) 402. The processor 402 may comprise at least one data processor for executing program components for executing user- or system-generated business processes. A user may include a network manager, an application developer, a programmer, an organization, or any system/sub-system being operated parallelly to the computer system 400. The processor 402 may include specialized processing units such as integrated system (bus) controllers, memory controllers/memory management control units, floating point units, graphics processing units, digital signal processing units, etc.

The processor 402 may be disposed in communication with one or more Input/Output (I/O) devices (411 and 412) via I/O interface 401. The I/O interface 401 may employ communication protocols/methods such as, without limitation, audio, analog, digital, stereo, IEEE®-1394, serial bus, Universal Serial Bus (USB), infrared, PS/2, BNC, coaxial, component, composite, Digital Visual Interface (DVI), high-definition multimedia interface (HDMI), Radio Frequency (RF) antennas, S-Video, Video Graphics Array (VGA), IEEE® 802.n/b/g/n/x, Bluetooth, cellular (e.g., Code-Division Multiple Access (CDMA), High-Speed Packet Access (HSPA+), Global System For Mobile Communications (GSM), Long-Term Evolution (LTE) or the like), etc. Using the I/O interface 401, the computer system 400 may communicate with one or more I/O devices 411 and 412.

In some embodiments, the processor 402 may be disposed in communication with a network 409 via a network interface 403. The network interface 403 may communicate with the network 409. The network interface 403 may employ connection protocols including, without limitation, direct connect, Ethernet (e.g., twisted pair 10/100/1000 Base T), Transmission Control Protocol/Internet Protocol (TCP/IP), token ring, IEEE® 802.11a/b/g/n/x, etc.

In an implementation, the preferred network 409 may be implemented as one of the several types of networks, such as intranet or Local Area Network (LAN) and such within the organization. The preferred network 409 may either be a dedicated network or a shared network, which represents an association of several types of networks that use a variety of protocols, for example, Hypertext Transfer Protocol (HTTP), Transmission Control Protocol/Internet Protocol (TCP/IP), Wireless Application Protocol (WAP) etc., to communicate with each other. Further, the network 409 may include a variety of network devices, including routers, bridges, RAN nodes, computing devices, storage devices, etc. Using the network interface 403 and the network 409, the computer system 400 may communicate with a user 103.

In some embodiments, the processor 402 may be disposed in communication with a memory 405 (e.g., RAM 413, ROM 414, etc. as shown in FIG. 6) via a storage interface 404. The storage interface 404 may connect to memory 405 including, without limitation, memory drives, removable disc drives, etc., employing connection protocols such as Serial Advanced Technology Attachment (SATA), Integrated Drive Electronics (IDE), IEEE-1394, Universal Serial Bus (USB), fiber channel, Small Computer Systems Interface (SCSI), etc. The memory drives may further include a drum, magnetic disc drive, magneto-optical drive, optical drive, Redundant Array of Independent Discs (RAID), solid-state memory devices, solid-state drives, etc.

The memory 405 may store a collection of program or database components, including, without limitation, user/application interface 406, an operating system 407, a web browser 408, and the like. In some embodiments, computer system 400 may store user/application data 406, such as the data, variables, records, etc. as described in this invention. Such databases may be implemented as fault-tolerant, relational, scalable, secure databases such as Oracle® or Sybase®.

The operating system 407 may facilitate resource management and operation of the computer system 400. Examples of operating systems include, without limitation, APPLE® MACINTOSH® OS XX, UNIX®, UNIX-like system distributions (E.G., BERKELEY SOFTWARE DISTRIBUTION® (BSD), FREEBSD®, NETBSD®, OPENBSD, etc.), LINUX® DISTRIBUTIONS (E.G., RED HAT®, UBUNTU®, KUBUNTU®, etc.), IBM® OS/2®, MICROSOFT® WINDOWS® (XP®, VISTA®/7/8, 10 etc.), APPLE® IOS®, GOOGLE™ ANDROID™, BLACKBERRY® OS, or the like.

The user interface 406 may facilitate display, execution, interaction, manipulation, or operation of program components through textual or graphical facilities. For example, the user interface 406 may provide computer interaction interface elements on a display system operatively connected to the computer system 400, such as cursors, icons, check boxes, menus, scrollers, windows, widgets, and the like. Further, Graphical User Interfaces (GUIs) may be employed, including, without limitation, APPLE® MACINTOSH® operating systems' Aqua®, IBM® OS/2®, MICROSOFT® WINDOWS® (e.g., Aero, Metro, etc.), web interface libraries (e.g., ActiveX®, JAVA®, JAVASCRIPT®, AJAX, HTML, ADOBE® FLASH®, etc.), or the like.

The web browser 408 may be a hypertext viewing application. Secure web browsing may be provided using Secure Hypertext Transport Protocol (HTTPS), Secure Sockets Layer (SSL), Transport Layer Security (TLS), and the like. The web browsers 408 may utilize facilities such as AJAX, DHTML, ADOBE® FLASH®, JAVASCRIPT®, JAVA®, Application Programming Interfaces (APIs), and the like. Further, the computer system 400 may implement a mail RAN node stored program component. The mail RAN node may utilize facilities such as ASP, ACTIVEX®, ANSI® C++/C#, MICROSOFT®, .NET, CGI SCRIPTS, JAVA®, JAVASCRIPT®, PERL®, PHP, PYTHON®, WEBOBJECTS®, etc. The mail RAN node may utilize communication protocols such as Internet Message Access Protocol (IMAP), Messaging Application Programming Interface (MAPI), MICROSOFT® exchange, Post Office Protocol (POP), Simple Mail Transfer Protocol (SMTP), or the like. In some embodiments, the computer system 400 may implement a mail client stored program component. The mail client may be a mail viewing application, such as APPLE® MAIL, MICROSOFT® ENTOURAGE®, MICROSOFT® OUTLOOK®, MOZILLA THUNDERBIRD®, and the like.

Furthermore, one or more computer-readable storage media may be utilized in implementing embodiments consistent with the present invention. A computer-readable storage medium refers to any type of physical memory on which information or data readable by a processor may be stored. Thus, a computer-readable storage medium may store instructions for execution by one or more processors, including instructions for causing the processor(s) to perform steps or stages consistent with the embodiments described herein. The term “computer-readable medium” should be understood to include tangible items and exclude carrier waves and transient signals, i.e., non-transitory. Examples include Random Access Memory (RAM), Read-Only Memory (ROM), volatile memory, nonvolatile memory, hard drives, Compact Disc (CD) ROMs, Digital Video Disc (DVDs), flash drives, disks, and any other known physical storage media.

In light of the technical advancements provided by the disclosed method, the claimed steps, as discussed above, are not routine, conventional, or not well-known aspects in the art, as the claimed steps provide the aforesaid solutions to the technical problems existing in the conventional technologies. Further, the claimed steps clearly bring an improvement in the functioning of the system itself, as the claimed steps provide a technical solution to a technical problem.

The terms “an embodiment”, “embodiment”, “embodiments”, “the embodiment”, “the embodiments”, “one or more embodiments”, “some embodiments”, and “one embodiment” mean “one or more (but not all) embodiments of the invention(s)” unless expressly specified otherwise.

The terms “including”, “comprising”, “having” and variations thereof mean “including but not limited to”, unless expressly specified otherwise.

The enumerated listing of items does not imply that any or all the items are mutually exclusive, unless expressly specified otherwise. The terms “a”, “an” and “the” mean “one or more”, unless expressly specified otherwise.

A description of an embodiment with several components in communication with each other does not imply that all such components are required. On the contrary, a variety of optional components are described to illustrate the wide variety of possible embodiments of the invention.

When a single device or article is described herein, it will be clear that more than one device/article (whether they cooperate) may be used in place of a single device/article. Similarly, where more than one device/article is described herein (whether they cooperate), it will be clear that a single device/article may be used in place of the more than one device/article or a different number of devices/articles may be used instead of the shown number of devices or programs. The functionality and/or features of a device may be alternatively embodied by one or more other devices which are not explicitly described as having such functionality/features. Thus, other embodiments of invention need not include the device itself.

Finally, the language used in the specification has been principally selected for readability and instructional purposes, and it may not have been selected to delineate or circumscribe the inventive subject matter. It is therefore intended that the scope of the invention be limited not by this detailed description, but rather by any claims that issue on an application based here on. Accordingly, the embodiments of the present invention are intended to be illustrative, but not limiting, of the scope of the invention, which is set forth in the following claims.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

1. A verification and debugging tool for Register Transfer Level (RTL) code, the verification and debugging tool comprising:
an input interface configured to receive RTL code in a Hardware Description Language (HDL);
an RTL parser configured to:
parse the RTL code, and
generate an abstract syntax tree of the RTL code;
a graph converter adapted to convert the abstract syntax tree into an RTL directed graph,
wherein the RTL directed graph comprises plurality of code blocks,
wherein each of the plurality of code blocks is represented as a node, and
wherein each node represents a functional block of the RTL code and each node comprise a node identifier, a fan-in parameter defining one or more input nodes, and a fanout parameter defining one or more output nodes;
a memory configured to store node block structures, wherein each node block structure comprises at least one of pointers to fan-in nodes, fanout nodes and one or more custom fields indicating behavior description of the node;
a visual display configured to display the RTL directed graph, wherein directional links indicate signal flow both upstream and downstream, enabling simultaneous visualization of multiple code blocks and corresponding interconnections.

2. The verification and debugging tool of claim 1, wherein each node of the RTL directed graph comprises at least one of a forward pointer to nodes for which the current node forms an input, and a backward pointer to nodes from which the current node receives an input.

3. The verification and debugging tool of claim 1, wherein the graph converter is further configured to represent signals of the RTL code as vertices of the RTL directed graph.

4. The verification and debugging tool of claim 1, further comprising:
an output interface configured to display debug information related to RTL code analysis and results.

5. The verification and debugging tool of claim 4, wherein the output interface is configurable to show results in a graphical format.

6. The verification and debugging tool of claim 1, wherein the one or more HDLs comprises at least one of Verilog and VHSIC Hardware Description Language (VHDL).

7. The verification and debugging tool of claim 1, wherein the input interface is further configured to validate syntax of the RTL code.

8. The verification and debugging tool of claim 1, wherein the graph converter is further configured to provide one or more customizable display options for the RTL directed graph.

9. The verification and debugging tool of claim 8, wherein the one or more customizable display options comprises at least one of color coding for different types of signals, adjustable node sizes, and selectable layers of data flow representation.

10. The verification and debugging tool of claim 1, wherein the visual display is configured to support zoom functionality for viewing details of individual code blocks or nodes.

11. The verification and debugging tool of claim 10, wherein the zoom functionality allows a user to focus on specific areas of the RTL directed graph while preserving the ability to return to an overall view.

12. The verification and debugging tool of claim 1, further comprises:
a user interface designed to allow user interactions within the visual display.

13. The verification and debugging tool of claim 12, wherein the user interface allows the user to group multiple code blocks into functional sections.

14. The verification and debugging tool of claim 1, wherein the RTL directed graph is configured to display at least one of control flow and data flow, wherein the at least one of the control flow and the data flow is displayed in a visually distinguishable manner.

15. The verification and debugging tool of claim 14, wherein the visual distinction between the control flow and the data flow is obtained using one of different arrow styles or different colors.

16. A method of providing Register Transfer Level (RTL) code block storage and analysis, the method comprising:
receiving RTL code in a Hardware Description Language (HDL);
parsing the RTL code, and generating an abstract syntax tree representing the syntactic structure of the RTL code;
converting the abstract syntax tree into an RTL directed graph,
wherein the RTL directed graph comprises plurality of code blocks, and
wherein each of the plurality of code blocks is represented as a node;
storing node block structures, wherein each node block structure comprises at least one of pointers to fan-in nodes, fanout nodes and one or more custom fields indicating behavior description of the node;
displaying the RTL directed graph, wherein directional links indicate signal flow both upstream and downstream, enabling simultaneous visualization of multiple code blocks and corresponding interconnections.

17. A non-transitory computer readable medium including instructions stored thereon that when processed by at least one processor, cause a verification and debugging tool to perform operations comprising:
receiving RTL code in a Hardware Description Language (HDL);
parsing the RTL code, and generating an abstract syntax tree representing the syntactic structure of the RTL code;
converting the abstract syntax tree into an RTL directed graph,
wherein the RTL directed graph comprises plurality of code blocks, and
wherein each of the plurality of code blocks is represented as a node;
storing node block structures, wherein each node block structure comprises at least one of pointers to fan-in nodes, fanout nodes and one or more custom fields indicating behavior description of the node;
displaying the RTL directed graph, wherein directional links indicate signal flow both upstream and downstream, enabling simultaneous visualization of multiple code blocks and corresponding interconnections.
